(19) United States
(12) Patent Application Publication
(10) Pub. No.: US 2021/0076048 A1
(43) Pub. Date: Mar. 11, 2021

(54) SYSTEM, APPARATUS AND METHOD FOR DATA COMPACTION AND DECOMPACTION

(71) Applicant: AGAPE-1 TECHNOLOGY INC., San Jose, CA (US)

(72) Inventor: Shih-Lun Chen, Taoyuan (TW)

(73) Assignee: AGAPE-1 TECHNOLOGY INC., San Jose, CA (US)

(21) Appl. No.: 16/684,977

(22) Filed: Nov. 15, 2019

Related U.S. Application Data
(63) Continuation of application No. 16/567,150, filed on Sep. 11, 2019.

(51) Int. Cl. H04N 19/146; H04N 19/184; H03M 7/30; H03M 7/40

(52) U.S. Cl. CPC H04N 19/146; H04N 19/184; H03M 7/4093; H03M 7/3059; H03M 7/6011

(57) ABSTRACT

A system, an apparatus and a method for encoding data are provided. The method includes (a) receiving encoded data; (b) determining a type of encoding scheme of the encoded data; (c) if the encoded data is determined as a first type of encoding scheme, decompressing the encoded data; and (d) if the encoded data is determined as a second type of encoding scheme different from the first type of encoding scheme, decompacting the encoded data. The first type of encoding scheme has a variable compression ratio. The second type of encoding scheme has a predetermined compaction ratio.

### CROSS-REFERENCE TO RELATED APPLICATIONS

This application is a continuation of U.S. patent application Ser. No. 16/567,150, filed Sep. 11, 2019, which is incorporated by reference herein in its entirety.

### BACKGROUND

### 1. Technical Field

The present disclosure relates to a system, an apparatus and a method for data compaction and decompaction.

### 2. Description of the Related Art

Data compaction or compression technique, which can involve encoding information or data with relatively less resource (e.g. bit(s) or byte(s)), may facilitate data storage, data transmission/communication or other application(s).

For example, a video encoder may adopt one or more visual encoding schemes (e.g., JPEG, MPEG, H264, H265, H266 or the like) to compress a video signal in a given communication bandwidth. The encoded video signal is transmitted to a receiver to be decoded by a suitable decoder. The encoded video signal may be stored in a storage device and then sent to a display device. The encoded video signal may be directly sent to the display device. However, the compression ratio of the visual encoding scheme varies, and sometimes the compression ratio may be low.

Lower compression ratio means that more memory capacity or more transmission bandwidth is required. In some applications, for example, in a virtual reality/augmented reality/substitution reality (AR/VR/SR) system or in an ultra-high definition (UHD) (4K/8K) TV, as the resolution of the display device increases, the memory capacity required for storing signals or data increases as well. This would significantly increase the manufacturing cost and the size of the device.

### SUMMARY

In accordance with some embodiments of the present disclosure, a method for decoding data includes (a) receiving encoded data; (b) determining a type of encoding scheme of the encoded data; (c) if the encoded data is determined as a first type of encoding scheme, decompressing the encoded data; and (d) if the encoded data is determined as a second type of encoding scheme different from the first type of encoding scheme, decompacting the encoded data. The first type of encoding scheme has a variable compression ratio. The second type of encoding scheme has a predetermined compaction ratio.

In accordance with some embodiments of the present disclosure, a decoding device includes a determination unit, a first decoding unit and a second decoding unit. The determination unit is configured to receive encoded data and to determine a type of encoding scheme of the encoded data. The first decoding unit is connected to the determination unit and configured to decompress the encoded data if the encoded data is determined as a first type of encoding scheme. The first type of encoding scheme having a variable compression ratio. The second decoding unit is connected to the determination unit and configured to decompact the encoded data if the encoded data is determined as a second type of encoding scheme different from the first type of encoding scheme. The second type of encoding scheme has a predetermined compaction ratio.

In accordance with some embodiments of the present disclosure, a non-transitory computer readable storage medium configured to store instructions that, when executed by a processor included in a computing device, cause the computing device to: receive encoded data; determine a type of encoding scheme of the encoded data; decompress the encoded data if the encoded data is determined as a first type of encoding scheme; and decompact the encoded data if the encoded data is determined as a second type of encoding scheme different from the first type of encoding scheme. The first type of encoding scheme has a variable compression ratio. The second type of encoding scheme has a predetermined compaction ratio.

### BRIEF DESCRIPTION OF THE DRAWINGS

FIG. 1 shows a block diagram of a system in accordance with some embodiments of the present disclosure.

FIG. 2 shows a block diagram of an encoder in accordance with some embodiments of the present disclosure.

FIG. 3 shows a block diagram of an encoder in accordance with some embodiments of the present disclosure.

FIG. 4 shows a block diagram of an encoder in accordance with some embodiments of the present disclosure.

FIG. 5A shows a simulation result of an encoder in accordance with some embodiments of the present disclosure.

FIG. 5B shows a simulation result of an encoder in accordance with some embodiments of the present disclosure.

FIG. 6 shows a block diagram of a decoder in accordance with some embodiments of the present disclosure.

Common reference numerals are used throughout the drawings and the detailed description to indicate the same or similar components. The present disclosure will be readily understood from the following detailed description taken in conjunction with the accompanying drawings.

### DETAILED DESCRIPTION

The terminology used herein is for the purpose of describing particular embodiments only, and is not intended to be limiting of the present disclosure. As used herein, the singular forms “a”, “an” and “the” are intended to include the plural forms as well, unless the context clearly indicates otherwise.

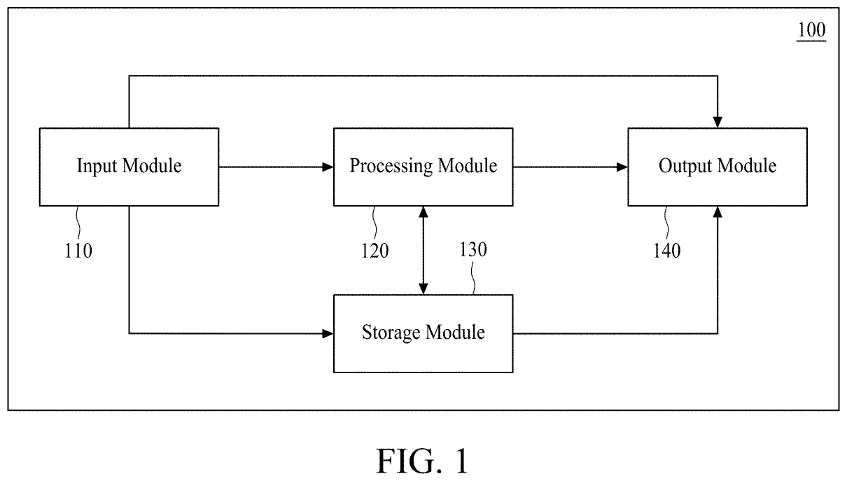

FIG. 1 shows a block diagram of a system 100, in accordance with some embodiments of the present disclosure. In some embodiments, the system 100 may be applicable to or included in an image system, a video system or any other display systems. The system 100 includes an input module 110, a processing module 120, a storage module 130 and an output module 140. In some embodiments, the above modules can be deleted or changed, or other additional modules can be added to the system 100 depending on different applications.

The input module 110 is configured to receive data (or signal, information or the like). The data received by the input module 110 may be raw data (uncompressed/uncompacted data) or compressed (or compacted) data. The input module 110 may be or may include an image/video capturing device, a network device and/or a data transmission device and/or the like. In some embodiments, the image/video capturing device (e.g., a camera) includes one or more image sensors, charge-coupled devices (CCD) or the like. In some embodiments, the network device includes a wireless network module (e.g., a Wi-Fi module, a mobile network module, a Bluetooth module or a Near-field communication module) and/or a wired network module (e.g., an Ethernet module). In some embodiments, the data transmission device includes a Universal Serial Bus (USB) module or a high definition multimedia interface (HDMI) module.

The processing module 120 is connected to the input module 110 and configured to process the data received by the input module 110. For example, the processing module 120 is configured to encode/decode, compress/decompress and/or compact/decompact the data received by the input module 110, if the data received by the input module 110 is the raw data. In some embodiments, the processing module 120 may include a processor (e.g., central processing unit (CPU), graphics processing unit (GPU), an encoder/decoder or any other suitable processing units). In some embodiments, the CPU, the GPU and the encoder/decoder are separate devices (e.g., chips or dies). Alternatively, the CPU, the GPU and the encoder/decoder may be integrated into a single device.

The storage module 130 is connected to the input module 110 to store the data received by the input module 110, if the data received by the input module 110 is the compressed data (or compacted data). The storage module 130 is connected to the processing module 120 to receive the compressed data from the processing module 120 and to store the compressed data. In some embodiments, the storage module 130 may include a volatile memory (e.g., dynamic random access memory (DRAM), static random access memory (SRAM) or the like) and/or a non-volatile memory (e.g., a hard drive disk, a flash memory, an optical storage device or the like).

The output module 140 is connected to receive the compressed/decompressed (or compacted/decompacted) data from the processing module 120 or the storage module 130 and to output the data. In some embodiments, the output module 140 may be or may include a display panel, a network device and/or a data transmission device and/or the like. In some embodiments, the network device includes a wireless network module (e.g., a Wi-Fi module, a mobile network module, a Bluetooth module or a Near-field communication module) and/or a wired network module (e.g., an Ethernet module). In some embodiments, the data transmission device includes a USB module or a HDMI module.

Some scenarios are provided below to show the applications of the system 100, in accordance with some embodiments of the present disclosure. Please be apprised that the system 100 can be also applicable in many other scenarios that are not described below.

Scenario 1: The system 100 is applicable to or included in an AR, a VR or a MR device.

In some embodiments, data (e.g., source data) may be obtained or received from the input module 110 (e.g., digital video camera). In some embodiments, the source data inputted from the input module 110 is real-time data. In some embodiments, the source data may be an image frame or a video frame including a sequence of image frames generated or captured by the input module 110. In some embodiments, the source data may be a bitstream, an image frame, a macroblock, a subblock or any other portion of a video frame. In some embodiments, partitioning a block into smaller blocks, for examples 1×4 pixels, 4×4 pixels, 8×8 pixels, can be the source data. The source data are transmitted to the processing module 120 (e.g., encoder, CPU or GPU) for compression. Alternatively, the source data can be compressed (or compacted) by the digital image camera directly. The compressed data are then transmitted to the storage module 130 and stored in the storage module 130.

In some embodiments, the source data may be obtained through wireless communication modules (e.g., Wi-Fi, Ethernet, mobile network or the like), HDMI interface or USB interface. The data are transmitted to the processing module 120 and compressed (or compacted) by the processing module 120 (e.g., encoder, CPU or GPU). The compressed data are then transmitted to the storage module 130 and stored in the storage module 130.

To display a video frame on a display panel of the AR, the VR or the MR device, the compressed (or compacted) data are decompressed (or decompacted) by the processing module 120 (e.g., decoder, CPU or GPU), and then the decompressed data are transmitted to the output module 140.

Scenario 2: The system 100 is applicable to or included in a TV or a video-streaming device (e.g., a set-top box or an endoscopic system).

In some embodiments, the operations of the system 100 in Scenario 2 are similar to those in Scenario 1, and the differences therebetween are described below. The source data are obtained or received from a HDMI interface, a USB interface Wi-Fi or Ethernet of the input module 110. The video frame (e.g., decompressed data) can be displayed on the panel of the TV directly (in the case that the system 100 is included in a TV) or through the HDMI interface, the USB interface, Wi-Fi or Ethernet of the output module 140 (in the case that the system 100 is included in a video-streaming device).

In some embodiments, the source data (raw data or original data) may be compressed by using a vision compression scheme (e.g., JPEG, JPEG2000, JPEG-LS, MPEG, H264, H265 or the like). Since the compression ratio (i.e., a ratio of a data size/bit length of the source data to a data size/bit length of the compressed data) of the vision compression scheme varies, it cannot be guaranteed that the compression ratio of each of the source data are equal to or higher than a target value (e.g., a threshold, a predetermined value, a target compression ratio). In other words, it cannot be guaranteed that the data size of the compressed data is equal to or less than a target data size. Therefore, the capacity of the memory required for storing the compressed data or the bandwidth of the network required for transmitting the compressed data should be designed or selected for a low compression ratio situation or for the worst case situation (e.g., in the case that the compression ratio is 1 or the data size of the compressed data is equal to the data size of the source data); otherwise, an error may occur. However, as the resolution of the display device increases, the memory capacity required for storing the compressed data increases as well. This would significantly increase the manufacturing cost and the size of the display device.

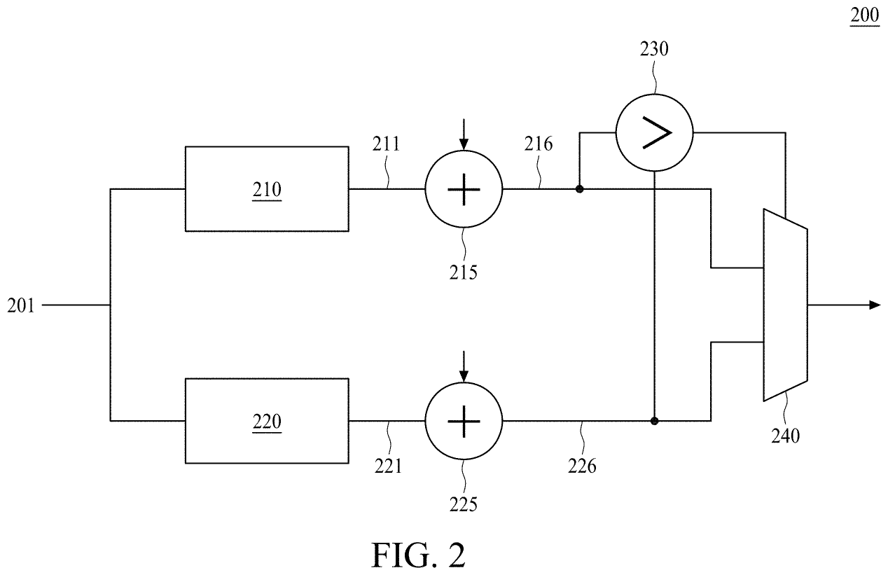

FIG. 2 depicts a block diagram of an encoder 200 in accordance with some embodiments of the present disclosure. In some embodiments, the encoder 200 can be included in the processing module 120 as shown in FIG. 1. In some embodiments, the encoder 200 can be included in the camera of the input module 110 or the storage module 130 as shown in FIG. 1. In some embodiments, the encoder 200 can be included in any electronic components which require a data coding operation. In some embodiments, the encoder 200 includes encoding modules 210, 220, a comparing module 230 and a selection module 240. In some embodiments, the encoder 200 can be implemented by software, hardware (e.g., a circuit, a chip or a die) or a combination thereof. For example, all of the encoding modules 210, 220, a comparing module 230 and a selection module 240 can be implemented by hardware or software. For example, a portion of the encoding modules 210, 220, a comparing module 230 and a selection module 240 can be implemented by hardware, while the rest can be implemented by software.

The encoding modules 210 and 220 are configured to receive source data 201. For example, the source data 201 are inputted to both the encoding modules 210 and 220. In some embodiments, the source data 201 may be an image frame or a video frame including a sequence of image frames generated or captured by the input module 110 as shown in FIG. 1. In some embodiments, the source data 201 may be a bitstream, an image frame, a macroblock, a subblock or any other portion of a video frame. In some embodiments, partitioning a block into smaller blocks, for examples 1×4, 4×4 pixels, 8×8 pixels, can be the source data 201.

The encoding module 210 is configured to perform one or more vision compression schemes to convert the source data 201 into compressed data 211. In some embodiments, the source data 201 is different from the compressed data 211. For example, a data size (bit number or bit length) of the source data 201 is different from that of the compressed data 211. In other embodiments, the source data 201 is the same as that of the compressed data 211. For example, a data size (bit number or bit length) of the source data 201 is the same as that of the compressed data 211. In other embodiments, a data size (bit number or bit length) of the compressed data 211 is greater than that the source data 201. In some embodiments, each of the vision compression schemes performed or adopted by the encoding module 210 has a variable compression ratio (i.e., a ratio of a data size/bit number of the source data 201 inputted to the encoding module 210 to a data size/bit number of the compressed data 211 outputted from the encoding module 210). For example, the compression ratio of the vision compression scheme performed or adopted by the encoding module 210 varies during the compression operation. In some embodiments, the vision compression schemes performed or adopted by the encoding module 210 include, for example, JPEG, JPEG2000, JPEG-LS, MPEG, H264, H265, H266 or any other vision encoding schemes.

The compressed data 211 is sent to a merging module 215 (or a packet module). The merging module 215 is configured to receive the compressed data 211 and to add (merge or combine) a code (e.g., an identification code) to the predetermined location of the compressed data 211 to generate compressed data 216. The code is added to the compressed data 211 to facilitate the decoding operation. In some embodiments, the code is an N-bit code, where N is an integer equal to or greater than 1. For example, the identification code may be “0” or “1.” In some embodiments, the code can be added before the most significant bit (MSB) of the compressed data 211 or after the least significant bit (LSB) of the compressed data 211 depending on different design requirements. For example, if the compressed data 211 has a pattern “0001,” the compressed data 216 may have a pattern “10001” or “00001.” In some embodiments, the merging module 215 may include a bit shifter and an adder.

The encoding module 220 is configured to perform one or more data compaction schemes to convert the source data 201 into compacted data 221. In some embodiments, the source data 201 is different from the compacted data 221. For example, a data size (bit number or bit length) of the source data 201 is different from that of the compacted data 221. In some embodiments, each of the data compaction schemes performed or adopted by the encoding module 220 has a predetermined compaction ratio (i.e., a ratio of a data size/bit number of the source data 201 inputted to the encoding module 220 to a data size/bit number of the compacted data 221 outputted from the encoding module 220). For example, each of the data compaction schemes performed or adopted by the encoding module 220 has a guaranteed Nx-compaction ratio, where N is greater than 1. For example, the compaction ratio of the data compaction scheme performed or adopted by the encoding module 220 would not change or vary during the compaction operation. In some embodiments, the data compaction schemes performed or adopted by the encoding module 220 include, for example, down-sampling, zooming out, scaling down, sampling, stuffing, filtering, interpolation, a combination thereof or any other data compaction schemes. A combination of the data compaction schemes means that the source data 201 may be performed by repeating one of down-sampling, zooming out, scaling down, sampling, stuffing, filtering or interpolation, or adopting at least one of said techniques to process data in parallel or sequentially.

The compacted data 221 is sent to a merging module 225. The merging module 225 is configured to receive the compacted data 221 and to add a code to the predetermined location of the compacted data 221 to generate compacted data 226. The code is added to the compacted data 221 to facilitate the decoding operation. In some embodiments, the code is an N-bit code, where N is an integer equal to or greater than 1. In some embodiments, the code can be added before the MSB of the compacted data 221 or after the LSB of the compacted data 221 depending on different design requirements. In some embodiments, the code added by the merging module 225 to the compacted data 221 is different from the code added by the merging module 215 to the compressed data 211. For example, the code added by the merging module 225 to the compacted data 221 is complementary to the code added by the merging module 215 to the compressed data 211. For example, if the merging module 215 adds a code “1” to the MSB of the compressed data 211, the merging module 225 would add a code “0” to the MSB of the compacted data 221, and vice versa.

In some embodiments, the comparing module 230 is configured to receive the compressed data 216 and to compare the compression ratio of the compressed data 216 with a predetermined value (e.g., a threshold value, a reference value or a target compression ratio). Alternatively, the comparing module 230 is configured to compare a data size/bit length of the compressed data with a predetermined data size/bit length. In some embodiments, the predetermined value is equal to the compaction ratio of the data compaction scheme performed or adopted by the encoding module 220.

Alternatively, the predetermined value is greater than or less than the compaction ratio of the data compaction scheme performed or adopted by the encoding module 220. In some embodiments, the comparing module 230 may be implemented by a comparator or by computer software.

The selection module 240 is configured to output the compressed data 216 if the compression ratio of the compressed data 216 is equal to or greater than the predetermined value. The selection module 240 is configured to output the compacted data 226 if the compression ratio of the compressed data 216 is less than the predetermined value. In some embodiments, the selection module 240 may be implemented by a multiplexer or by computer software.

In some embodiments, the comparing module 230 is configured to receive both the compressed data 216 and the compacted data 226, and to compare the compression ratio (or data size/bit length) of the compressed data 216 with the compaction ratio (or data size/bit length) of the compacted data 226. The selection module 240 is configured to output the compressed data 216 if the compression ratio of the compressed data 216 is equal to or greater than the compaction ratio of the compacted data 226. The selection module 240 is configured to output the compacted data 226 if the compression ratio of the compressed data 216 is less than the compaction ratio of the compacted data 226.

In accordance with the embodiments as shown in FIG. 2, it is guaranteed that the compression ratio (or the compaction ratio) of data outputted from the encoder 200 is equal to or greater than the predetermined value. For example, if the predetermined value is set to twelve, the lowest compression ratio (or the compaction ratio) of data outputted from the encoder 200 is twelve. In other words, the compression ratio (or the compaction ratio) of data (the compressed data or the compacted data) outputted from the encoder 200 is equal to or greater than twelve. Hence, it is guaranteed that the data size of the data outputted from the encoder 200 is equal to or less than a predetermined data size. Therefore, the capacity of the memory required for storing the compressed data (or the compacted data) or the bandwidth of the network required for transmitting the compressed data (or the compacted data) can be designed or selected for storing or transmitting the data with the predetermined data size. In other words, it is unnecessary to design or select memory with a relatively large capacity or a network with a relatively large bandwidth for the low compression ratio situation (e.g., the compression ratio is less than the predetermined value). This would reduce the manufacturing cost or the size of the system 100.

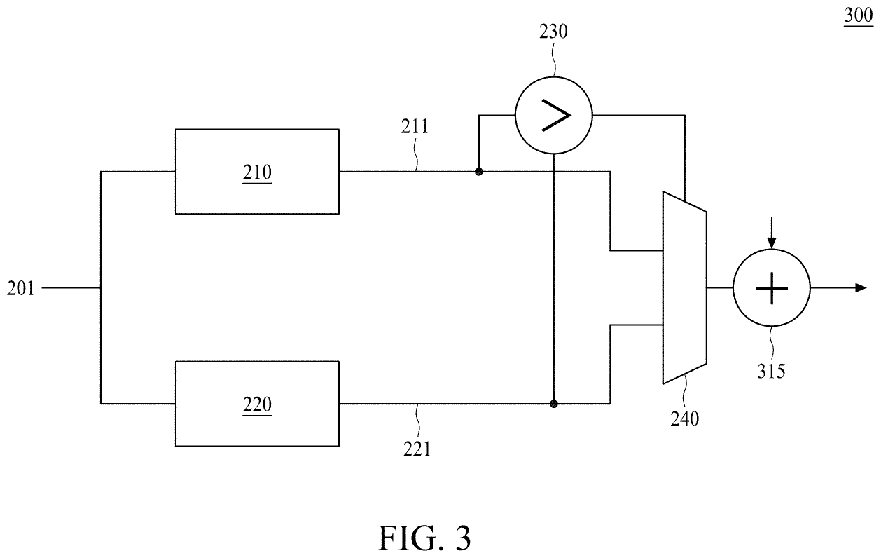

FIG. 3 depicts a block diagram of an encoder 300 in accordance with some embodiments of the present disclosure. In some embodiments, the encoder 300 can be included in the processing module 120 as shown in FIG. 1. In some embodiments, the encoder 300 can be included in the camera of the input module 110 as shown in FIG. 1. In some embodiments, the encoder 300 can be included in any electronic components which require a data coding operation. The encoder 300 illustrated in FIG. 3 is similar to the encoder 200 illustrated in FIG. 2, and the differences therebetween are described below.

As shown in FIG. 3, a merging module 315 is connected to the output of the selection module 240, while in FIG. 2, the merging module 215 (or the merging module 225) is connected to the input of the selection module 240.

In some embodiments, the comparing module 230 is configured to receive the compressed data 211 and to compare the compression ratio of the compressed data 211 with a predetermined value (e.g., a threshold value, a reference value or a target value). The selection module 240 is configured to output the compressed data 211 if the compression ratio of the compressed data 211 is equal to or greater than the predetermined value. The selection module 240 is configured to output the compacted data 221 if the compression ratio of the compressed data 211 is less than the predetermined value.

In some embodiments, the comparing module 230 is configured to receive both the compressed data 211 and the compacted data 221, and to compare the compression ratio of the compressed data 211 with the compaction ratio of the compacted data 211. The selection module 240 is configured to output the compressed data 211 if the compression ratio of the compressed data 211 is equal to or greater than the compaction ratio of the compacted data 221. The selection module 240 is configured to output the compacted data 221 if the compression ratio of the compressed data 211 is less than the compaction ratio of the compacted data 221.

After the selection module 240 outputs the compressed data 211 or the compacted data 221, the merging module 315 is configured to add a code to the predetermined location of the compressed data 211 or the compacted data 221. The code is added to the compressed data 211 or the compacted data 221 to facilitate the decoding operation. In some embodiments, the code is an N-bit code, where N is an integer equal to or greater than 1. In some embodiments, the code can be added before the MSB or after the LSB of the compressed data 211 or the compacted data 221 depending on different design requirements. The code added to the compressed data 211 is different from the code added to the compacted data 221.

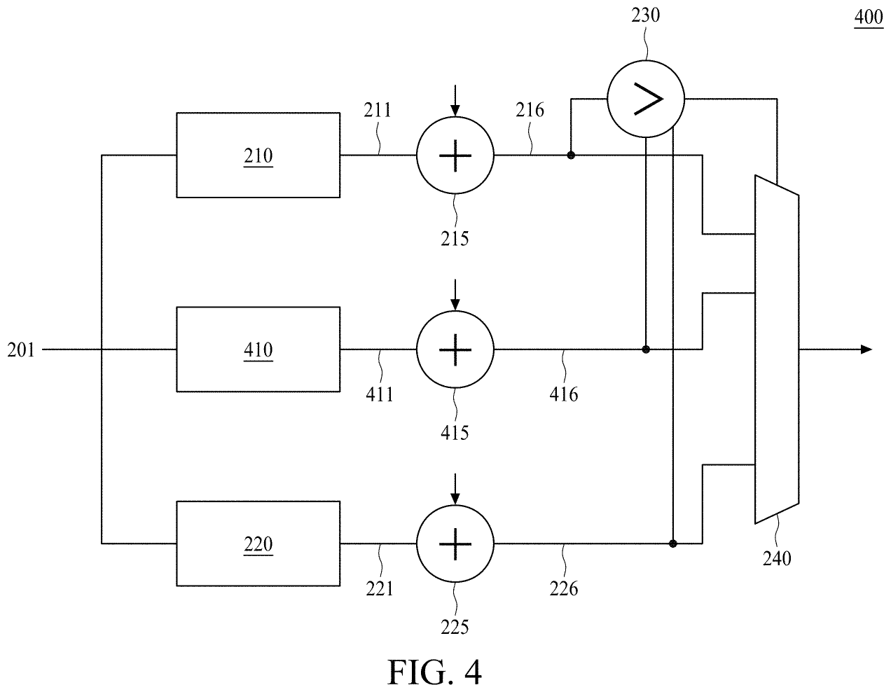

FIG. 4 depicts a block diagram of an encoder 400 in accordance with some embodiments of the present disclosure. In some embodiments, the encoder 400 can be included in the processing module 120 as shown in FIG. 1. In some embodiments, the encoder 400 can be included in the camera of the input module 110 as shown in FIG. 1. In some embodiments, the encoder 400 can be included in any electronic components which require a data coding operation. The encoder 400 illustrated in FIG. 4 is similar to the encoder 200 illustrated in FIG. 2, except that the encoder 400 further includes an encoding module 410 and a merging module 415.

The encoding module 410 is configured to perform one or more vision compression schemes to convert the source data 201 into compressed data 411. The vision compression scheme performed or adopted by the encoding module 410 is different form the vision compression scheme performed or adopted by the encoding module 210.

The compressed data 411 is sent to a merging module 415. The merging module 415 is configured to receive the compressed data 411 and to add a code to the predetermined location of the compressed data 411 to generate compressed data 416. The code is added to the compressed data 411 to facilitate the decoding operation. In some embodiments, the code is an N-bit code, where N is an integer equal to or greater than 2. In some embodiments, the encoder 400 may include any number of encoding modules, which are configured to perform one or more vision compression schemes depending on different design requirements. The vision compression schemes performed or adopted by the encoding modules are different from each other. In such embodiments, the code is an N-bit code, and the number of the encoding modules (including the encoding modules performing vision compression schemes and the encoding module performing a data compaction scheme) is equal to or less than 2^{N}.

In some embodiments, the comparing module 230 is configured to receive the compressed data 216 and 416 and to compare the compression ratio of the compressed data 216 and 416 with a predetermined value (e.g., a threshold value, a reference value or a target value). If the compression ratios of both the compressed data 216 and 416 are equal to or greater than the predetermined value, the compressed data with a relatively higher compression ratio is outputted from the selection module 240. If the compression ratio of one of the compressed data 216 and 416 is equal to or greater than the predetermined value, the compressed data with the compression ratio greater than the predetermined value is outputted from the selection module 240. If the compression ratios of both the compressed data 216 and 416 are less than the predetermined value, the compacted data 226 is outputted from the selection module 240.

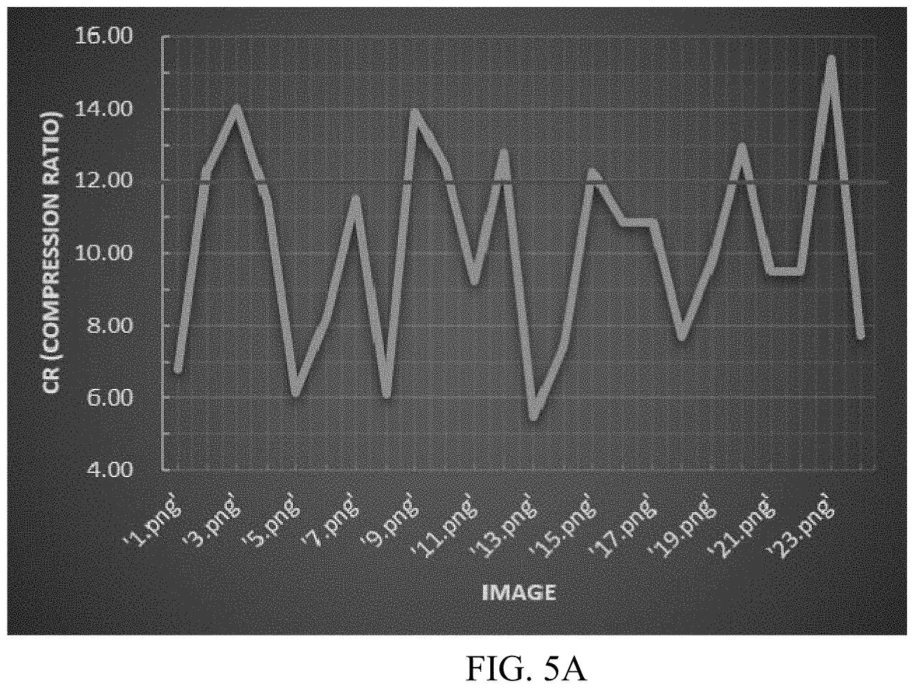

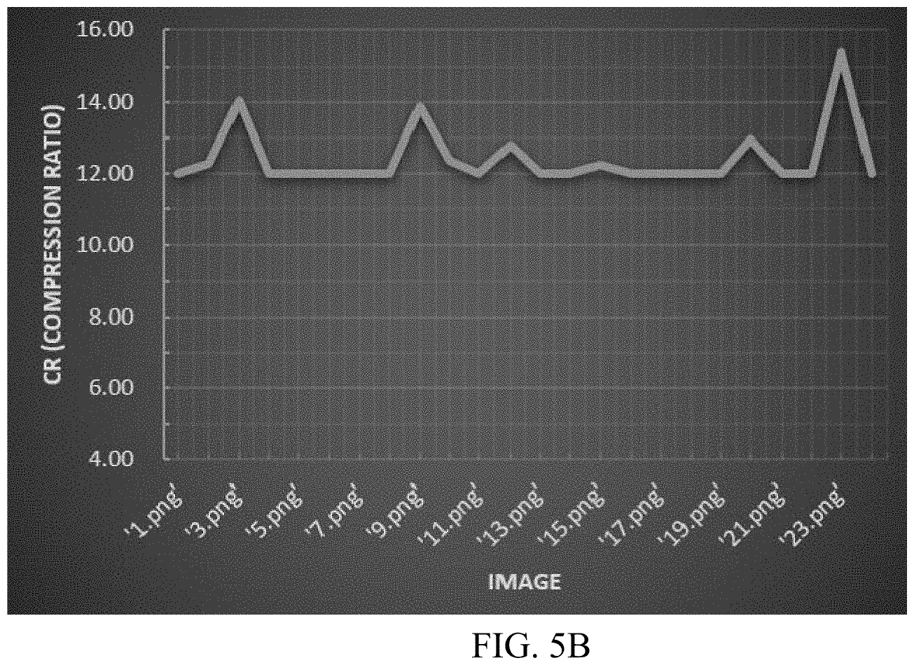

FIG. 5A illustrates a simulation result of an encoder performing a vision compression scheme, in accordance with some embodiments of the present disclosure. In some embodiments, the vision compression scheme performed or adopted by the encoder in FIG. 5A is the JPEG compression scheme. In some embodiments, the source data inputted to the encoder in FIG. 5A includes 24 images (e.g., standard Kodak images). As shown in FIG. 5A, the x-axis represents 24 images, and the y-axis represents the compression ratio performed by the encoder using the JPEG compression scheme for each of the images.

As shown in FIG. 5A, the compression ratio for the images varies. For example, the highest compression ratio, which is achieved for the 23rd image (i.e., 23.png as shown in FIG. 5A) is about 15.5, and the lowest compression ratio, which is achieved for the 13th image (i.e., 13.png as shown in FIG. 5A) is about 5.5. If the target compression ratio is set to twelve, many of the 24 images fail to achieve the target compression ratio. Since it cannot be guaranteed that the compression ratio of each of the images is equal to or higher than the target compression ratio, the capacity of the memory required for storing the compressed data or the bandwidth of the network required for transmitting the compressed data should be designed or selected for the low compression ratio situation or for the worst case situation (in this case, the lowest compression ratio is about 5.5); otherwise, an error may occur.

FIG. 5B illustrates a simulation result of the encoder 200 as shown in FIG. 2, in accordance with some embodiments of the present disclosure. In the embodiments of FIG. 5B, the vision compression scheme performed or adopted by the encoding module 210 is the JPEG compression scheme, and the data compaction scheme performed or adopted by the encoding module 220 is the 12× down-sampling scheme. The source data inputted to the encoder 200 is the same as the source data inputted to the encoder as shown in FIG. 5A. As shown in FIG. 5B, the x-axis represents 24 images, and the y-axis represents the compression ratio or compaction ratio performed by the encoder 200 for each of the images.

As shown in FIG. 5B, if the compression ratio performed by the encoding module 210 is less than the target compression ratio (e.g., twelve), the selection module 240 is configured to output the compacted data generated by the encoding module 220. Therefore, as shown in FIG. 5B, it is guaranteed that all of the compression/compaction ratios of 24 images are equal to or higher than the target compression ratio (e.g., twelve). Therefore, the capacity of the memory required for storing the compressed data (or the compacted data) or the bandwidth of the network required for transmitting the compressed data (or the compacted data) can be designed or selected for storing or transmitting the data with the predetermined data size.

Take the simulation results in FIG. 5A as an example, the original size of the 13^{th} image is 1,179,648 bytes, and the compression ratio for the 13^{th} image is about 5.5. Hence, the data size of the compressed image of the 13^{th} image is about 214,481 bytes. As shown in FIG. 5B, compaction ratio for the 13^{th} image is 12. Hence, the data size of the compacted image of the 13^{th} image is about 98,304 bytes. Compared to the use of only the JPEG compression scheme, using both the JPEG compression scheme and the 12× down-sampling scheme can reduce more than 50% data size.

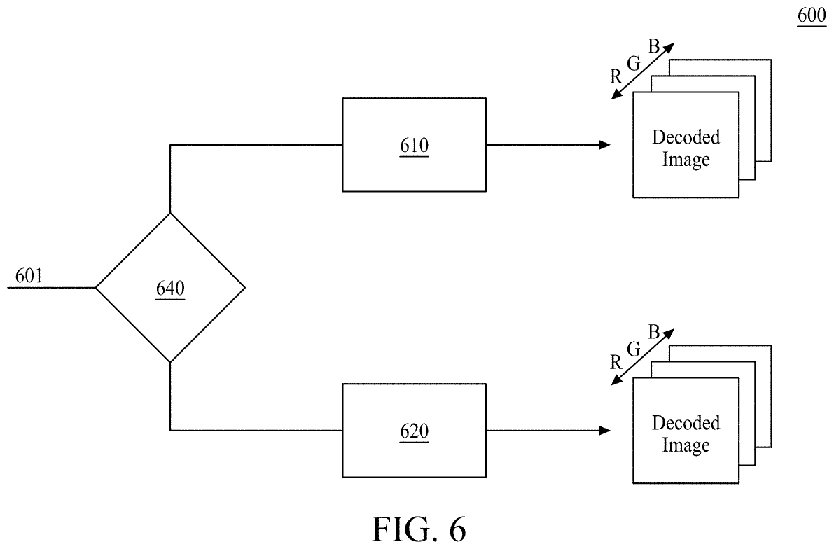

FIG. 6 depicts a block diagram of a decoder 600 in accordance with some embodiments of the present disclosure. In some embodiments, the decoder 600 can be included in the processing module 120 as shown in FIG. 1. In some embodiments, the decoder 600 can be included in the camera of the output module 140 as shown in FIG. 1. In some embodiments, the decoder 600 can be included in any electronic components which require a data decoding operation. In some embodiments, the decoder 600 includes a selection module 640 and decoding modules 610 and 620. In other embodiments, the decoder 600 may include more than two decoding modules depending on the number of the encoding modules of the corresponding encoder. For example, if the decoder 600 is designed to decode the compressed/compacted data from the encoder 200 as shown in FIG. 2, the decoder 600 may include two decoding modules. For example, if the decoder 600 is designed to decode the compressed/compacted data from the encoder 300 as shown in FIG. 3, the decoder 600 may include three decoding modules. For example, if the decoder 600 is designed to decode the compressed/compacted data from an encoder including N encoding modules, the decoder 600 may include N decoding modules. In some embodiments, the decoder 600 can be implemented by software, hardware (e.g., a circuit, a chip or a die) or a combination thereof. For example, all of the selection module 640 and the decoding modules 610 and 620 can be implemented by hardware or software. For example, a portion of the selection module 640 and the decoding modules 610 and 620 can be implemented by hardware, while the rest can be implemented by software.

The decoding module 610 is configured to perform one or more vision decompression schemes to convert the compressed data into decoded data (e.g., decoded images or decoded video). In some embodiments, the vision decompression schemes performed or adopted by the decoding module 610 include, for example, JPEG, JPEG2000, JPEG-LS, MPEG, H264, H265, H266 and any other vision decoding schemes.

The decoding module 620 is configured to perform one or more data decompaction schemes to convert the compacted data into decoded data (e.g., decoded images or decoded video). In some embodiments, the data decompaction schemes performed or adopted by the decoding module 620 include, for example, up-sampling, zooming in, scaling up, demosaicing, interpolation, a combination thereof or any other data decompaction schemes. A combination of the data decompaction schemes means that the compacted data may be performed by repeating one of down-sampling, zooming out, scaling down, filtering, stuffing or interpolation, or adopting at least one of said techniques to process data in parallel or sequentially.

The selection module 640 is configured to receive encoded data 601. In some embodiments, the encoded data 601 is generated by the encoder 200, 300 or 400 as shown in FIG. 2, 3 or 4. For example, the encoded data 601 may include the compressed data 216, 416, the compacted data 226 as shown in FIG. 2, 3 or 4, or a combination thereof. In other embodiments, the encoded data 601 may be generated by other encoders. The selection module 640 is configured to determine which decoding module (e.g., the decoding module 610 or 620) is selected to decode the encoded data 601. In some embodiments, the decoding module is selected by the selection module 640 depending on the code (i.e., the identification code) added to the predetermined location of the compressed/compacted data by the merging module 210, 220 or 420 as shown in FIG. 2, 3 or 4. For example, if the selection module 640 identifies that the identification code of the encoded data 601 is added by the merging module 215 (or 415), the encoded data 601 is determined to be the compressed data, and the selection module 640 is configured to send the encoded data 601 to the decoding module 610 for decompression. If the selection module 640 identifies that the identification code of the encoded data 601 is added by the merging module 225, the encoded data 601 is determined to be the compacted data, and the selection module 640 is configured to send the encoded data 601 to the decoding module 620 for decompaction.

The various aspects, embodiments, implementations or features of the described embodiments can be used separately or in any combination. Various aspects of the described embodiments can be implemented by software, hardware or a combination of hardware and software. The described embodiments can also be embodied as computer readable code on a computer readable medium. The computer readable medium is any data storage device that can store data which can thereafter be read by a computer system. Examples of the computer readable medium include read-only memory, random-access memory, CD-ROMs, DVDs, magnetic tape, hard disk drives, solid state drives, and optical data storage devices. The computer readable medium can also be distributed over network-coupled computer systems so that the computer readable code is stored and executed in a distributed fashion.

As used herein, the terms “substantially,” “substantial,” “approximately,” and “about” are used to denote and account for small variations. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. As another example, a thickness of a film or a layer being “substantially uniform” can refer to a standard deviation of less than or equal to ±10% of an average thickness of the film or the layer, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Additionally, amounts, ratios, and other numerical values are sometimes presented herein in a range format. It can be understood that such range formats are used for convenience and brevity, and should be understood flexibly to include not only numerical values explicitly specified as limits of a range, but also all individual numerical values or sub-ranges encompassed within that range as if each numerical value and sub-range is explicitly specified.

While the present disclosure has been described and illustrated with reference to specific embodiments thereof, these descriptions and illustrations do not limit the present disclosure. It can be clearly understood by those skilled in the art that various changes may be made, and equivalent elements may be substituted within the embodiments without departing from the true spirit and scope of the present disclosure as defined by the appended claims. The illustrations may not necessarily be drawn to scale. There may be distinctions between the artistic renditions in the present disclosure and the actual apparatus, due to variables in manufacturing processes and such. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it can be understood that these operations may be combined, sub-divided, or re-ordered to form an equivalent method without departing from the teachings of the present disclosure. Therefore, unless specifically indicated herein, the order and grouping of the operations are not limitations of the present disclosure.

What is claimed is:

1. A method for decoding data, comprising:
(a) receiving encoded data;
(b) determining a type of encoding scheme of the encoded data;
(c) if the encoded data is determined as a first type of encoding scheme, decompressing the encoded data, the first type of encoding scheme having a variable compression ratio; and
(d) if the encoded data is determined as a second type of encoding scheme different from the first type of encoding scheme, decompacting the encoded data, the second type of encoding scheme having a predetermined compaction ratio.

2. The method of claim 1, wherein the determining step comprises determining the type of encoding scheme based on one or more predetermined bits of the encoded data.

3. The method of claim 1, wherein a compression ratio of the encoded data belonging to the first type of encoding scheme is equal to or greater than a compaction ratio of the encoded data belonging to the second type of encoding scheme.

4. The method of claim 3, wherein the encoded data belonging to the second type of encoding scheme Nx-compaction ratio, where N is greater than 3.

5. The method of claim 1, wherein the decompressed data or the decompacted data includes a bitstream, an image frame, a video frame, a macroblock in an image frame, a macroblock in a video frame, a subblock in an image frame or a subblock in a video frame.

6. The method of claim 1, wherein the encoded data is decompressed by at least one of the following decompression schemes: JPEG, JPEG2000, JPEG-LS, MPEG, H264, H265, H266.

7. The method of claim 1, wherein the encoded data is decompacted by at least one of the following decompaction schemes: up-sampling, zooming in, scaling up, demosaicing, interpolation.

8. A decoding device comprising:
a determination unit configured to receive encoded data and to determine a type of encoding scheme of the encoded data;
a first decoding unit connected to the determination unit and configured to decompress the encoded data if the encoded data is determined as a first type of encoding scheme, the first type of encoding scheme having a variable compression ratio; and
a second decoding unit connected to the determination unit and configured to decompact the encoded data if the encoded data is determined as a second type of encoding scheme different from the first type of encoding scheme, the second type of encoding scheme having a predetermined compaction ratio.

9. The decoding device of claim 8, wherein the type of the encoding scheme of the encoded data is determined based on one or more predetermined bits of the encoded data.

10. The decoding device of claim 8, wherein a compression ratio of the encoded data belonging to the first type of encoding scheme is equal to or greater than a compaction ratio of the encoded data belonging to the second type of encoding scheme.

11. The decoding device of claim 10, wherein the encoded data belonging to the second type of encoding scheme Nx-compaction ratio, where N is greater than 3.

12. The decoding device of claim 8, wherein the decompressed data or the decompacted data includes a bitstream, an image frame, a video frame, a macroblock in an image frame, a macroblock in a video frame, a subblock in an image frame or a subblock in a video frame.

13. The decoding device of claim 8, wherein the first decoding unit is configured to perform at least one of the following decompression schemes: JPEG, JPEG2000, JPEG-LS, MPEG, H264, H265 and H266.

14. The decoding device of claim 8, wherein the second decoding unit is configured to perform at least one of the following decompaction schemes: up-sampling, zooming in, scaling up, demosaicing and interpolation.

15. A computer readable storage medium configured to store instructions that, when executed by a processor included in a computing device, cause the computing device to:
receive encoded data;
determine a type of encoding scheme of the encoded data;
decompress the encoded data if the encoded data is determined as a first type of encoding scheme, the first type of encoding scheme having a variable compression ratio; and
decompact the encoded data if the encoded data is determined as a second type of encoding scheme different from the first type of encoding scheme, the second type of encoding scheme having a predetermined compaction ratio.

16. The computer readable storage medium of claim 15, wherein the type of the encoding scheme of the encoded data is determined based on one or more predetermined bits of the encoded data.

17. The computer readable storage medium of claim 15, wherein a compression ratio of the encoded data belonging to the first type of encoding scheme is equal to or greater than a compaction ratio of the encoded data belonging to the second type of encoding scheme.

18. The computer readable storage medium of claim 15, wherein the encoded data belonging to the second type of encoding scheme Nx-compaction ratio, where N is greater than 3.

19. The computer readable storage medium of claim 15, wherein the decompressed data or the decompacted data includes a bitstream, an image frame, a video frame, a macroblock in an image frame, a macroblock in a video frame, a subblock in an image frame or a subblock in a video frame.

20. The computer readable storage medium of claim 15, wherein the encoded data is decompressed by at least one of the following decompression schemes: JPEG, JPEG2000, JPEG-LS, MPEG, H264, H265, H266.

21. The computer readable storage medium of claim 15, wherein the encoded data is decompacted by at least one of the following decompaction schemes: up-sampling, zooming in, scaling up, demosaicing, interpolation.
